(19) United States
(12) Patent Application Publication
(10) Pub. No.: US 2023/0207652 A1
(43) Pub. Date: Jun. 29, 2023

(54) NANOSHEET DEVICE HAVING TWO BOTTOM ISOLATION LAYERS

(71) Applicant: INTERNATIONAL BUSINESS MACHINES CORPORATION, Armonk, NY (US)

(72) Inventors: Shogo Mochizuki, Mechanicville, NY (US); Kangguo Cheng, Schenectady, NY (US); Juntao Li, Cohoes, NY (US)

(21) Appl. No.: 17/563,714

(22) Filed: Dec. 28, 2021

(51) Int. Cl. H01L 29/423; H01L 29/66; H01L 29/78; H01L 29/786; H01L 29/06

(52) U.S. Cl. CPC H01L 29/42392; H01L 29/6653; H01L 29/7848; H01L 29/78696; H01L 29/0665

(57) ABSTRACT

A gate-all-around device is provided. The gate-all-around device includes a source/drain on a substrate, an isolation liner wrapped around the source/drain, where the isolation liner separates the source/drain from the substrate, and a one or more nanosheet channel sections electrically connected to the source/drain.

### BACKGROUND

The present invention generally relates to bottom isolation of nanosheet devices, and more particularly to a gate-all-around (GAA) nanosheet (NS) device having two bottom isolation layers.

### SUMMARY

In accordance with an embodiment of the present invention, a gate-all-around device is provided. The gate-all-around device includes a source/drain on a substrate, an isolation liner wrapped around the source/drain, where the isolation liner separates the source/drain from the substrate, and a one or more nanosheet channel sections electrically connected to the source/drain.

In accordance with another embodiment of the present invention, a gate-all-around device is provided. The gate-all-around device includes a source/drain on a substrate, and an isolation liner between the first source/drain and the substrate. The gate-all-around device further includes a first set of one or more nanosheet channel sections adjoining the first source/drain on a first side, and a second set of one or more nanosheet channel sections adjoining a second side of the first source/drain opposite the first side, wherein the first source/drain imparts a stress to both the first set and the second set of nanosheet channel sections without plastic strain relaxation.

In accordance with yet another embodiment of the present invention, a method of forming a gate-all-around device is provided. The method includes forming a sacrificial plate on a substrate, wherein the sacrificial plate is adjacent to a stack of alternating one or more nanosheet channel sections and one or more sacrificial sections, and epitaxially growing a source/drain on the sacrificial plate, wherein the source/drain is electrically connected to the one or more nanosheet channel sections. The method further includes removing the sacrificial plate, and forming an isolation liner on and beneath the source/drain.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 illustrates perpendicular cross-sectional side views showing a stack of alternating nanosheet channel sections and sacrificial sections on a bottom insulating layer and substrate, and the bottom insulating layer between stacks, in accordance with an embodiment of the present invention;

FIG. 2 illustrates perpendicular cross-sectional side views showing removal of a portion of the bottom insulating layer between the stacks and between the shallow trench isolation regions, in accordance with an embodiment of the present invention;

FIG. 3 illustrates perpendicular cross-sectional side views showing formation of sacrificial plates on the substrate between the stacks and shallow trench isolation regions, in accordance with an embodiment of the present invention;

FIG. 4 illustrates perpendicular cross-sectional side views showing formation of source/drain layers on the sacrificial plates, in accordance with an embodiment of the present invention;

FIG. 5 illustrates perpendicular cross-sectional side views showing formation of source/drains on the sacrificial plates, in accordance with an embodiment of the present invention;

FIG. 6 illustrates perpendicular cross-sectional side views showing removal of a portion of the shallow trench isolation regions between the sacrificial plates, in accordance with an embodiment of the present invention;

FIG. 7 illustrates perpendicular cross-sectional side views showing removal of the sacrificial plates beneath the source/drains and between portions of the bottom insulating layer, in accordance with an embodiment of the present invention;

FIG. 8 illustrates perpendicular cross-sectional side views showing formation of an isolation liner on and beneath the source/drains and adjacent to the portions of the bottom insulating slabs, in accordance with an embodiment of the present invention;

FIG. 9 illustrates perpendicular cross-sectional side views showing formation of an interlayer dielectric (ILD) layer on the isolation liner and source/drains, in accordance with an embodiment of the present invention;

FIG. 10 illustrates perpendicular cross-sectional side views showing removal of the dummy gate caps from the dummy gate structures, and planarization of the gate sidewall spacers, in accordance with an embodiment of the present invention;

FIG. 11 illustrates perpendicular cross-sectional side views showing removal of the dummy gate fill from between the gate sidewall spacers, and removal of the sacrificial sections from the stack, in accordance with an embodiment of the present invention;

FIG. 12 illustrates perpendicular cross-sectional side views showing removal of the sacrificial sections from the stack, in accordance with an embodiment of the present invention;

FIG. 13 illustrates perpendicular cross-sectional side views showing formation of an active gate structure on the nanosheet channel sections, in accordance with an embodiment of the present invention;

FIG. 14 illustrates perpendicular cross-sectional side views showing a stack of alternating nanosheet channel layers and sacrificial layers directly on a substrate, and shallow trench isolation regions adjacent to the stacks, in accordance with another embodiment of the present invention;

FIG. 15 illustrates perpendicular cross-sectional side views showing formation of a dummy gate structure on a stack of alternating nanosheet channel sections and sacrificial sections directly on the substrate, and inner spacers adjacent to the sacrificial sections, in accordance with another embodiment of the present invention;

FIG. 16 illustrates perpendicular cross-sectional side views showing formation of sacrificial plates on the substrate between the stacks and shallow trench isolation regions, in accordance with another embodiment of the present invention; and

FIG. 17 illustrates perpendicular cross-sectional side views showing formation of source/drains and an active gate structure on the nanosheet channel sections, in accordance with another embodiment of the present invention.

### DETAILED DESCRIPTION

Embodiments of the present invention provide a gate-all-around nanosheet device structure having two bottom dielectric isolation (BDI) layers, where a first BDI layer is between the active gate structure and the substrate, and a replacement BDI layer is between the source/drain(s) and the substrate.

Embodiments of the present invention provide a method of epitaxially growing source/drains on the substrate and replacing a sacrificial plate with a second bottom dielectric isolation (BDI) layer between the source/drain epi and the substrate. Epitaxial growth of the source/drain from the sacrificial plate and substrate can avoid strain relaxation of the source/drains due to the free surface when grown from the end faces of the nanosheet channel sections. Strain relaxation of the source/drains epitaxially grown from the end faces of the nanosheet channel sections without using the substrate and sacrificial plate as a growth template can result in crystalline defects, such as stacking faults and dislocations, to form in the source/drains. The growth of source/drains having a different material composition that the nanosheet channel sections from which the source/drains are epitaxial grown can result in plastic strain relaxation of the source/drains that introduce crystal defects. The plastic strain relaxation can result from having a free surface of the growing source/drain opposite the growth surface without a substrate surface acting as a growth template. The plastic strain relaxation can reduce or eliminate the stress to be imparted to the device channel(s).

Embodiments of the present invention provide effective strain introduction into nanosheet channels due to having source/drain epitaxial growth up from the substrate surface, where stress can be compressive for pFETs and tensile for nFETs. Bottom-up source/drain epitaxial growth from a sacrificial plate can provide tensile or compressive strain in the nanosheet channel sections.

Exemplary applications/uses to which the present invention can be applied include, but are not limited to: Logic devices, including, but not limited to, NAND gates, NOR gates, and processors (e.g., CPUs, GPUs).

It is to be understood that aspects of the present invention will be described in terms of a given illustrative architecture; however, other architectures, structures, substrate materials and process features and steps can be varied within the scope of aspects of the present invention.

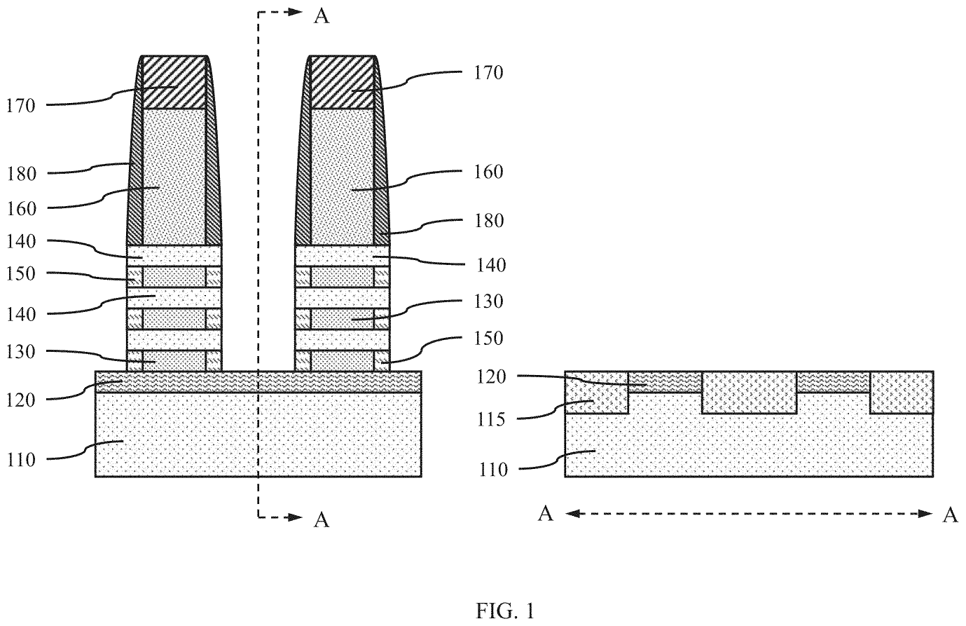

Referring now to the drawings in which like numerals represent the same or similar elements and initially to FIG. 1, FIG. 1 illustrates perpendicular cross-sectional side views showing a stack of alternating nanosheet channel sections and sacrificial sections on a bottom insulating layer and substrate, and the bottom insulating layer between stacks, in accordance with an embodiment of the present invention.

In one or more embodiments, the substrate 110 can be a semiconductor substrate, where the substrate 110 can be a type IV semiconductor, for example, silicon (Si) or germanium (Ge), or a type IV-IV compound semiconductor, for example, silicon-germanium (SiGe) or silicon carbide (SiC), a type III-V compound semiconductor, for example, gallium arsenide (GaAs), gallium nitride (GaN), or indium phosphide (InP). The substrate material can be a single crystal semiconductor suitable for epitaxial growth of a stack of alternating nanosheet channel layers and sacrificial layers.

In one or more embodiments, shallow trench isolation (STI) regions 115 can be formed in the substrate 110, where the STI regions 115 can be formed by lithographic processes, etching trenches, and deposition of an electrically insulating dielectric material in the trenches.

In various embodiments, a shallow trench isolation (STI) regions 115 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In one or more embodiments, a bottom insulating layer 120 can be formed on the substrate 110, where the bottom insulating layer 120 can be formed by replacement of a bottom sacrificial layer with an electrically insulating dielectric material.

In various embodiments, a bottom insulating layer 120 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In one or more embodiments, the nanosheet channel sections 140 can be, for example, silicon (Si) nanosheet sections formed on the bottom sacrificial layer and substrate 110 by epitaxial growth. In various embodiments, the nanosheet channel sections 140 can be nanowires or nano-ellipses; however, the term “nanosheet” is used for consistency to refer to each of these nano-forms.

In various embodiment the nanosheet channel sections 140 can have a thickness in a range of about 3 nanometers (nm) to about 15 nm, or about 4 nm to about 9 nm, although other thicknesses are also contemplated.

In one or more embodiments, the sacrificial sections 130 can be, for example, silicon-germanium (SiGe) nanosheet sections formed on the nanosheet channel sections 140 by epitaxial growth to form the alternating stack of nanosheet channel sections 140 and sacrificial sections 130.

In various embodiments, the sacrificial sections 130 can have a thickness in a range of about 6 nanometers (nm) to about 20 nm, or about 8 nm to about 15 nm, although other thicknesses are also contemplated.

In various embodiments, the sacrificial sections 130 can be silicon-germanium (SiGe) with about a germanium concentration of about 15 atomic percent (at. %) to about 35 atomic percent (at. %), or about 25 atomic percent (at. %).

In one or more embodiments, inner spacers 150 can be formed in inner spacer cavities created by recessing the sacrificial sections 130. The inner spacers 150 can be formed by a conformal deposition.

In various embodiments, the inner spacers 150 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In one or more embodiments, a dummy gate structure can be on the stack of nanosheet channel sections 140 and sacrificial sections 130, where the dummy gate structure can include a dummy gate fill on the nanosheet channel sections 140 and sacrificial sections 130 and a dummy gate cap 170 on the dummy gate fill 160. Gate sidewall spacers 180 can be formed on the dummy gate structure.

In various embodiments, the dummy gate cap 170 and gate sidewall spacers 180 can each be a dielectric hardmask material, including, but not limited to, silicon oxide (SiO), silicon nitride (SiN), silicon oxynitride (SiON), silicon boronitride (SiBN), titanium nitride (TiN), and combinations thereof. The dummy gate fill 160 can be a selectively removable material, including, but not limited to, amorphous silicon (a-Si), amorphous germanium (a-Ge), amorphous carbon (a-C), and combinations thereof.

As shown in the A-A cross-section, a top surface of the bottom insulating layer 120 can be exposed between the stacks and between the shallow trench isolation regions 115.

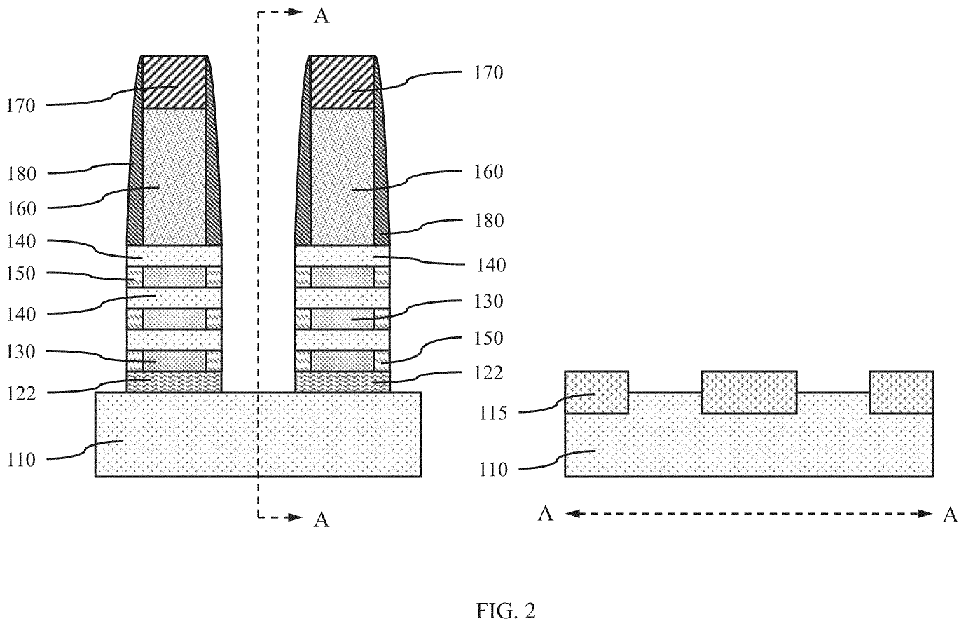

FIG. 2 illustrates perpendicular cross-sectional side views showing removal of a portion of the bottom insulating layer between the stacks and between the shallow trench isolation regions, in accordance with an embodiment of the present invention.

In one or more embodiments, a portion of the bottom insulating layer 120 between stacks and between shallow trench isolation regions can be removed using a selective directional etch, for example, a reactive ion etch (RIE), where removal of the portion of the bottom insulating layer 120 can leave bottom insulating slabs 122 beneath the stack of alternating nanosheet channel sections 140 and sacrificial sections 130. The bottom insulating slabs 122 can physically and electrically separate the bottom most sacrificial section 140 from the substrate 110. Removal of the portion of the bottom insulating layer 120 between the stacks and between the shallow trench isolation regions 115 can expose portions of the substrate 110.

As shown in the A-A cross-section, a top surface of the substrate 110 can be exposed between the stacks and between the shallow trench isolation regions 115.

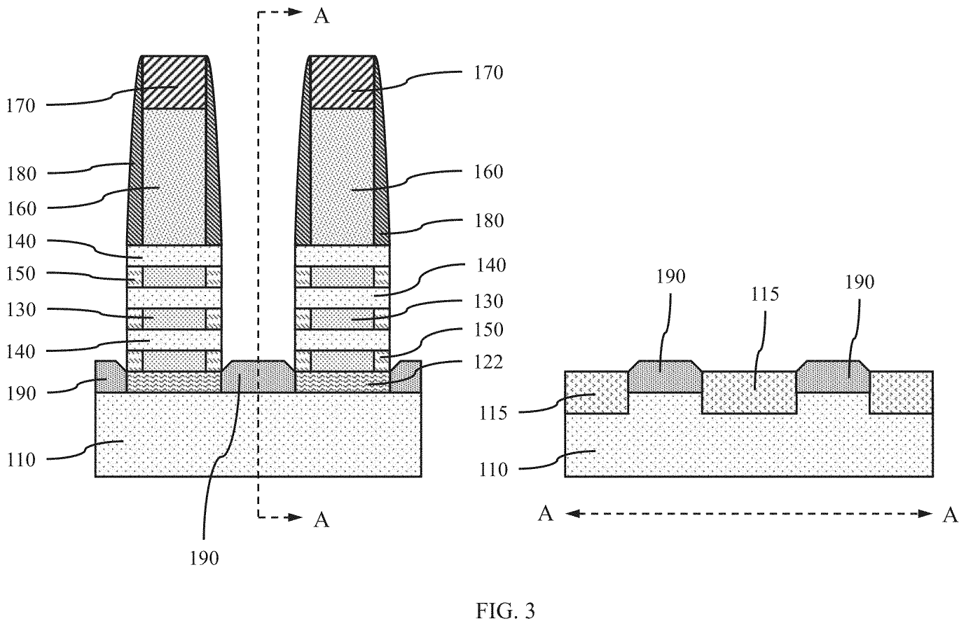

FIG. 3 illustrates perpendicular cross-sectional side views showing formation of sacrificial plates on the substrate between the stacks and shallow trench isolation regions, in accordance with an embodiment of the present invention.

In one or more embodiments, sacrificial plates 190 can be formed on the exposed surface of substrate between the stacks and between the shallow trench isolation regions 115, where the sacrificial plates 190 can be formed by epitaxial growth from the exposed surface of substrate 110. The sacrificial plates 190 can fill in the space between the stacks and shallow trench isolation regions 115. A top surface of the sacrificial plates 190 can be above the top surface of the shallow trench isolation regions 115 and the bottom insulating slabs 122.

In various embodiments, the sacrificial plates 190 can be, for example, silicon-germanium (SiGe) with a germanium concentration in a range of about 45 atomic percent (at. %) to about 75 at. %, or about 60 at. %. The sacrificial plates 190 can act as buffer layers between a silicon substrate and a silicon germanium source/drain formed on the sacrificial plates 190.

As shown in the A-A cross-section, the sacrificial plates 190 can be formed between the bottom insulating slabs 122 and between the shallow trench isolation regions 115.

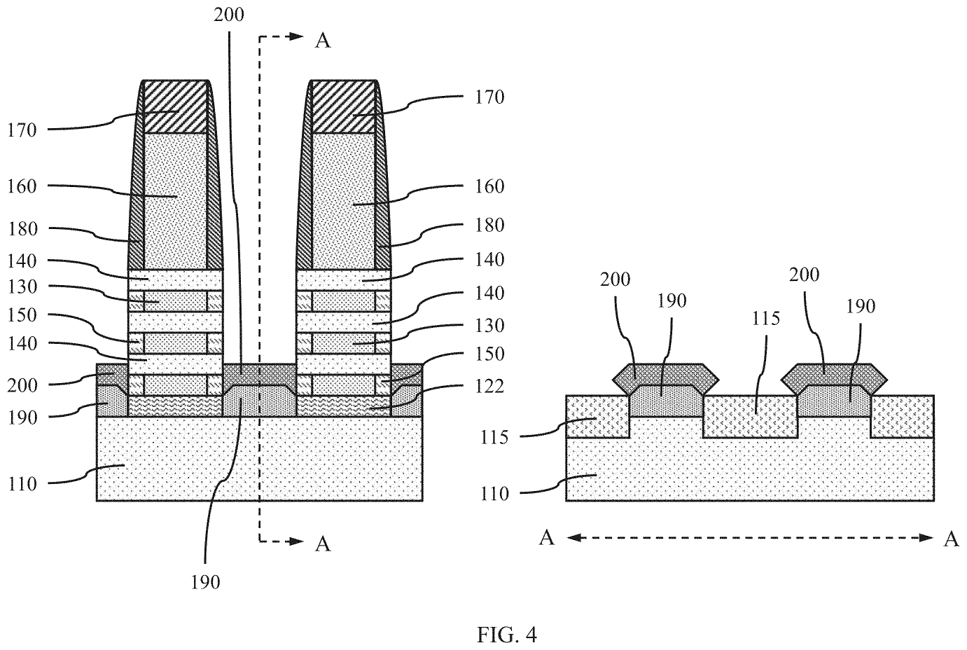

FIG. 4 illustrates perpendicular cross-sectional side views showing formation of source/drain layers on the sacrificial plates, in accordance with an embodiment of the present invention.

In one or more embodiments, a source/drain layer 200 can be formed on the sacrificial plate 190, where the source/drain layer 200 can be formed by epitaxial growth. The initial source/drain layer 200 can grow outwardly from the facets of the sacrificial plate 190 and vertically along the sidewalls of the stacks of nanosheet channel sections 140. The source/drain layer 200 can be doped in situ as the source/drain layer 200 grows. The source/drain layer 200 can be doped with n-type dopants (e.g., phosphorus (P)) or p-type dopants (e.g., boron (B)) depending on whether an n-type device or a p-type device is being fabricated.

In various embodiments, the source/drain layer 200 can be silicon (Si) for an n-type device, or silicon-germanium (SiGe) for a p-type device.

As shown in the A-A cross-section, the source/drain layer 200 can be formed on the sacrificial plates 190 between the nanosheet channel sections 140 and between the shallow trench isolation regions 115. The source/drain layer 200 can extend over the shallow trench isolation regions 115.

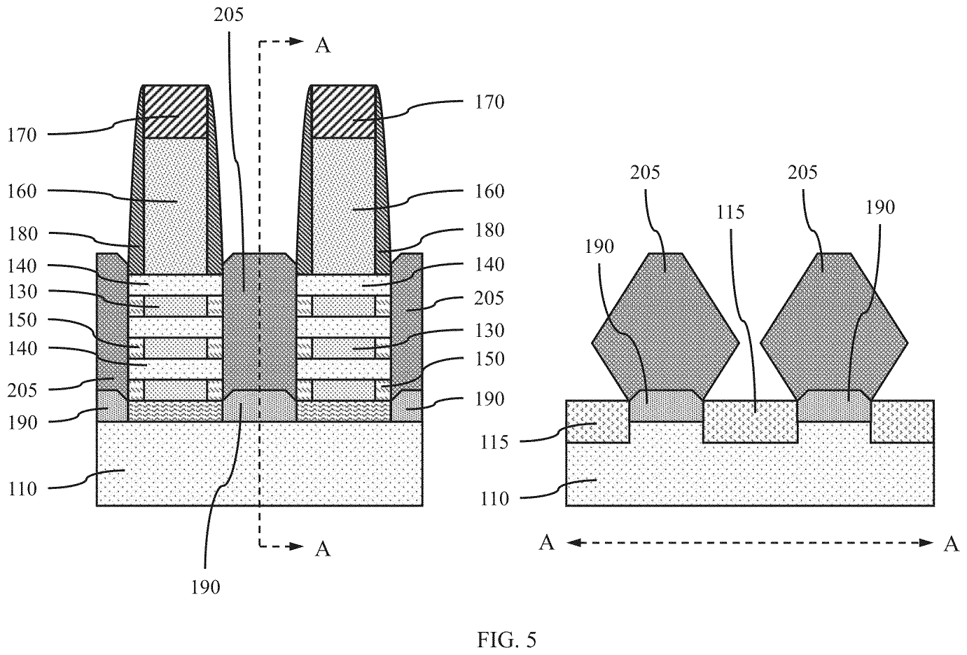

FIG. 5 illustrates perpendicular cross-sectional side views showing formation of source/drains on the sacrificial plates, in accordance with an embodiment of the present invention.

In one or more embodiments, the source/drain layer 200 can be grown vertically to form a source/drain 205 that covers the end faces of each of the nanosheet channel sections 140 in the stack. The source/drain 205 can extend above the top most nanosheet channel section 140 and laterally over the shallow trench isolation (STI) regions 115. The source/drains 205 can be adjacent to a lower portion of the gate sidewall spacers 180. The source/drains 205 can be doped with n-type dopants (e.g., phosphorus (P)) or p-type dopants (e.g., boron (B)) depending on whether an n-type device or a p-type device is being fabricated.

In various embodiments, the source/drains 205 can impart a tensile stress in the direction of electrical current flow to the nanosheet channel sections 140 in the nFET region.

In various embodiments, the source/drains 205 can impart a compressive stress in the direction of electrical current flow to the nanosheet channel sections 140 in the pFET region.

As shown in the A-A cross-section, the source/drains 205 can be grown from the source/drain layer 200, where the source/drains 205 can be between the nanosheet channel sections 140.

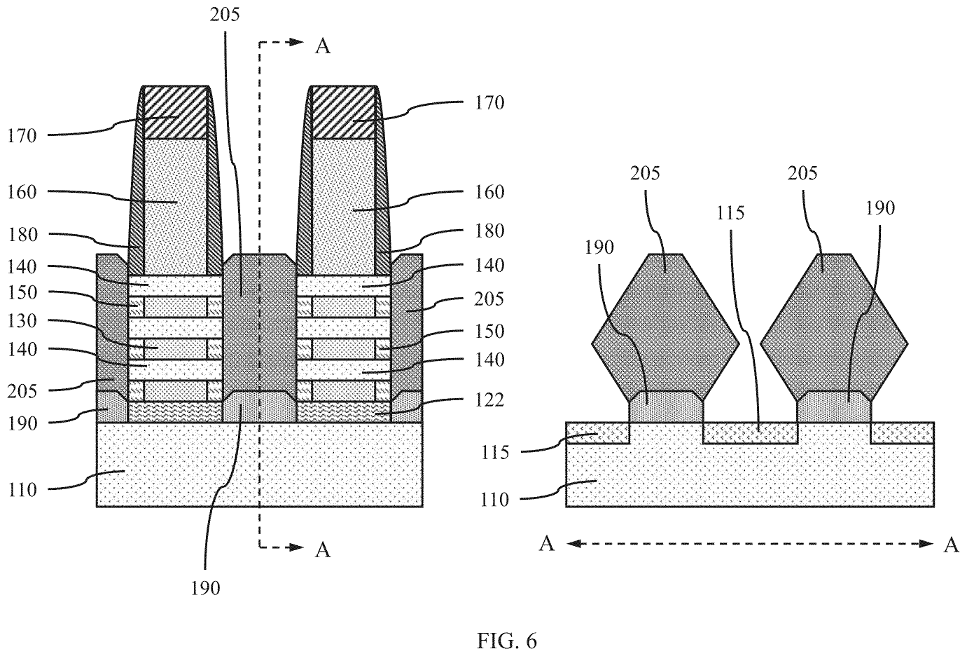

FIG. 6 illustrates perpendicular cross-sectional side views showing removal of a portion of the shallow trench isolation regions between the sacrificial plates, in accordance with an embodiment of the present invention.

In one or more embodiments, the shallow trench isolation (STI) regions 115 can be recessed using a selective, isotropic etch, where the top surface of the shallow trench isolation (STI) regions 115 can be lowered to be approximately coplanar with the interface between the bottom surface of the sacrificial plate 190 and top surface of the substrate 110. Removal of the upper portion of the shallow trench isolation (STI) regions 115 can expose the sidewalls of the sacrificial plates 190.

As shown in the A-A cross-section, the height of the shallow trench isolation (STI) regions 115 can be reduced to expose the sides of the sacrificial plate 190.

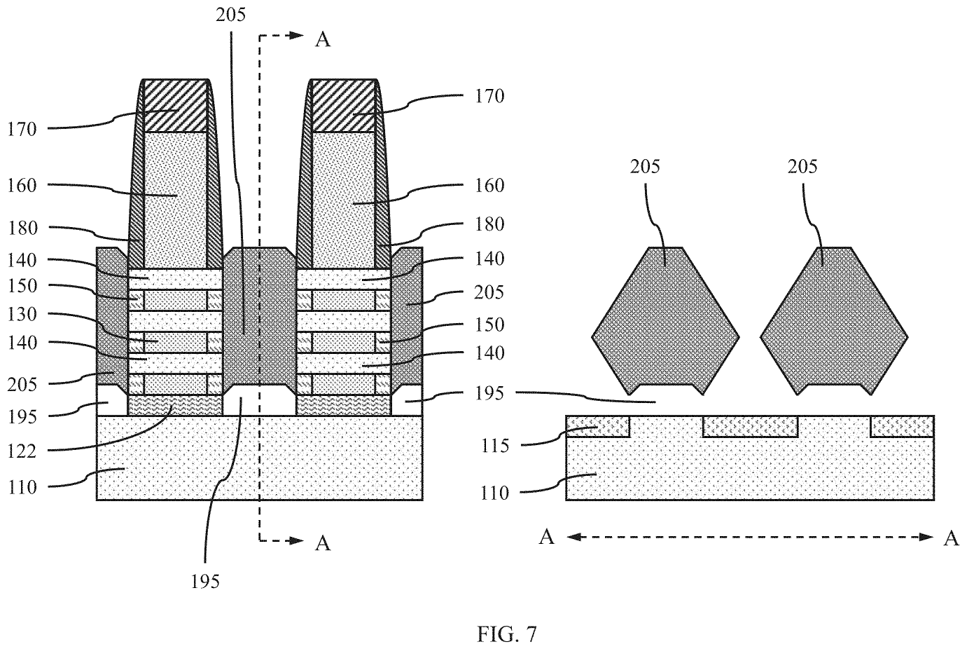

FIG. 7 illustrates perpendicular cross-sectional side views showing removal of the sacrificial plates beneath the source/drains and between portions of the bottom insulating layer, in accordance with an embodiment of the present invention.

In one or more embodiments, the sacrificial plates 190 can be removed using a selective isotropic etch to form a conduit 195 between the source/drains 205 and the substrate 110, where the bottom insulating slabs 122 remain on opposite sides of the conduit 195. The conduit 195 can pass beneath the source/drain 205, where the source/drain 205 remains suspended between the stacks.

As shown in the A-A cross-section, the conduit 195 can extend to beneath the source/drain 205.

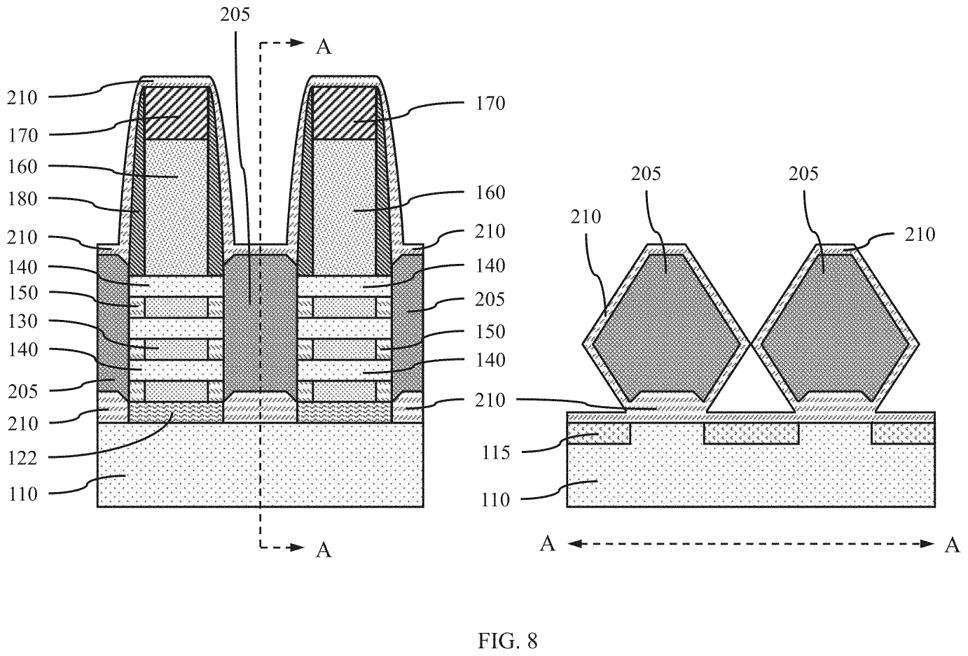

FIG. 8 illustrates perpendicular cross-sectional side views showing formation of an isolation liner on and beneath the source/drains and adjacent to the portions of the bottom insulating slabs, in accordance with an embodiment of the present invention.

In one or more embodiments, an isolation liner 210 can be formed on and beneath the source/drains 205 and adjacent to the portions of the bottom insulating slabs 122, where the isolation liner 210 can be formed by a conformal deposition that fills in the conduit 195. The isolation liner 210 can wrap around the source/drains 205, and can cover the STI regions 115, where the isolation liner 210 can separate the source/drain from the substrate. The isolation liner 210 between the source/drain and the substrate can reduce or eliminate source/drain leakage to the substrate 110. The isolation liner 210 can be formed on the gate sidewall spacers 180 and dummy gate caps 170 by the conformal deposition.

In various embodiments, the isolation liner 210 can be can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof. In various embodiments, the bottom insulating slab 122 and the isolation liner 210 can be made of different electrically insulating dielectric materials.

In various embodiments, the isolation liner 210 can have a thickness in a range of about 3 nanometers (nm) to about 15 nm, or about 4 nm to about 9 nm, although other thicknesses are also contemplated. The thickness can be sufficient to fill in the conduit 195.

As shown in the A-A cross-section, the isolation liner 210 can fill in the conduit 195 beneath the source/drain 205 and cover the STI regions 115.

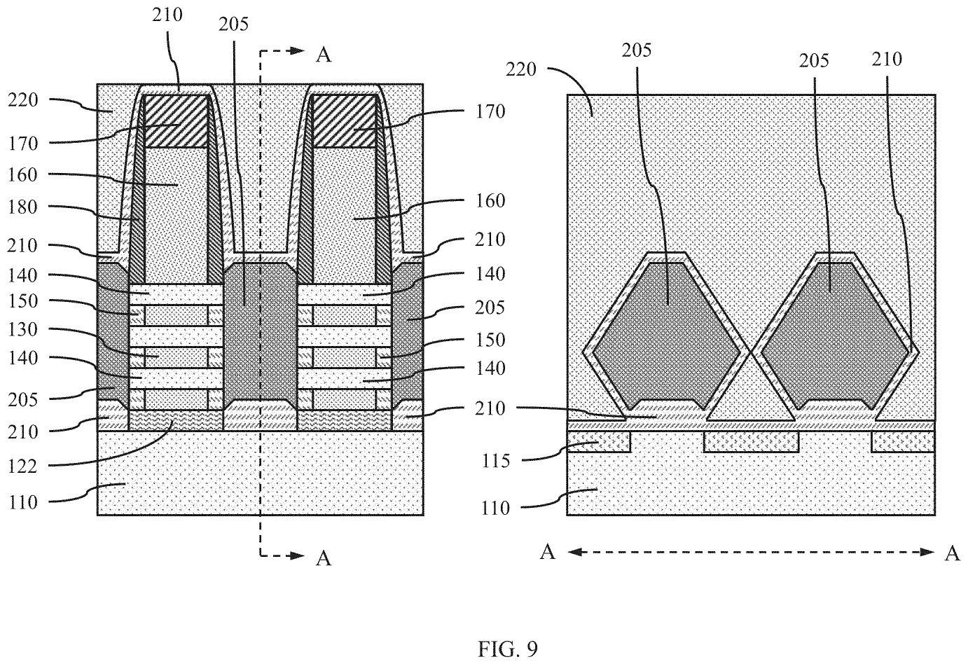

FIG. 9 illustrates perpendicular cross-sectional side views showing formation of an interlayer dielectric (ILD) layer on the isolation liner and source/drains, in accordance with an embodiment of the present invention.

In one or more embodiments, an interlayer dielectric (ILD) layer 220 can be formed on the isolation liner 210 and source/drains 205, where the ILD layer 220 can be formed by a blanket deposition. The isolation liner 210 can separate the interlayer dielectric (ILD) layer 220 from the source/drains 205.

In various embodiments, the interlayer dielectric (ILD) layer 220 can be can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof. The ILD layer 220 can be a different dielectric material from the isolation liner 210.

As shown in the A-A cross-section, the ILD layer 220 can fill in the space between the source/drains 205.

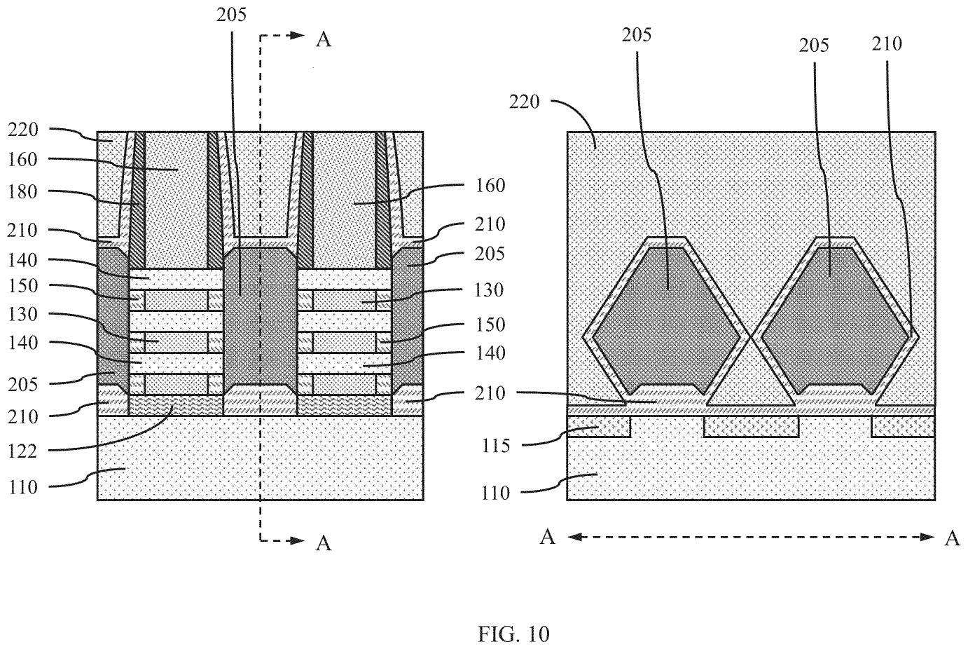

FIG. 10 illustrates perpendicular cross-sectional side views showing removal of the dummy gate caps from the dummy gate structures, and planarization of the gate sidewall spacers, in accordance with an embodiment of the present invention.

In one or more embodiments, the dummy gate caps 170 and an upper portion of the gate sidewall spacers 180, isolation liner 210, and ILD layer 220 can be removed to expose the dummy gate fill 160. The dummy gate caps 170 and an upper portion of the gate sidewall spacers 180, isolation liner 210, and ILD layer 220 can be removed using selective etching and/or a chemical-mechanical polishing (CMP) to provide a uniform surface.

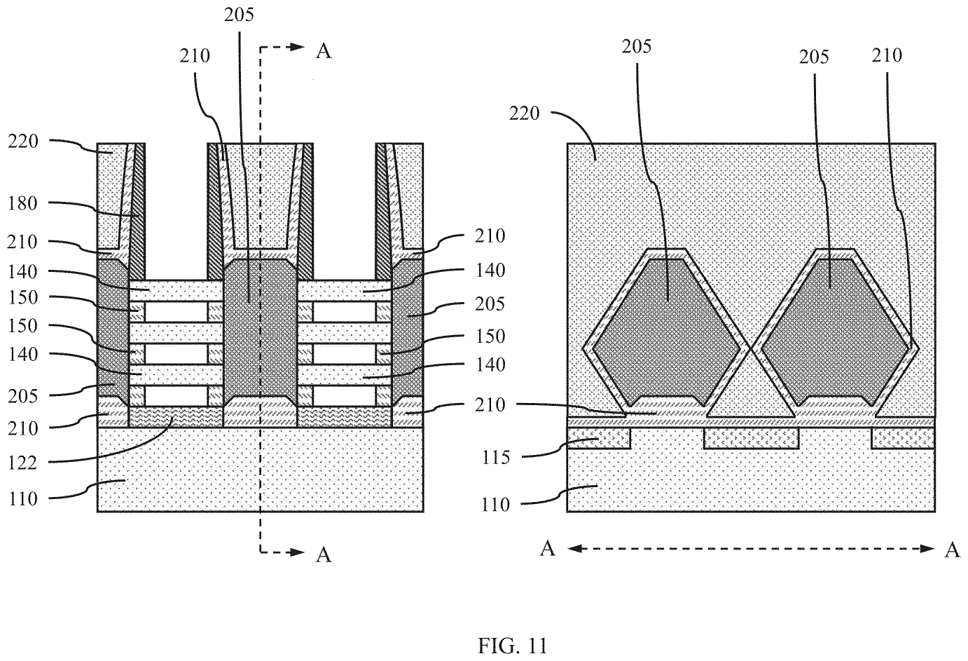

FIG. 11 illustrates perpendicular cross-sectional side views showing removal of the dummy gate fill from between the gate sidewall spacers, and removal of the sacrificial sections from the stack, in accordance with an embodiment of the present invention.

In one or more embodiments, the dummy gate fill 160 and sacrificial sections 130 can be removed using one or more selective isotropic etches. Removal of the dummy gate fill 160 and sacrificial sections 130 can expose portions of the nanosheet channel sections 140 between the inner spacers 150. A portion of the top surface of the bottom insulating slabs 122 can also be exposed.

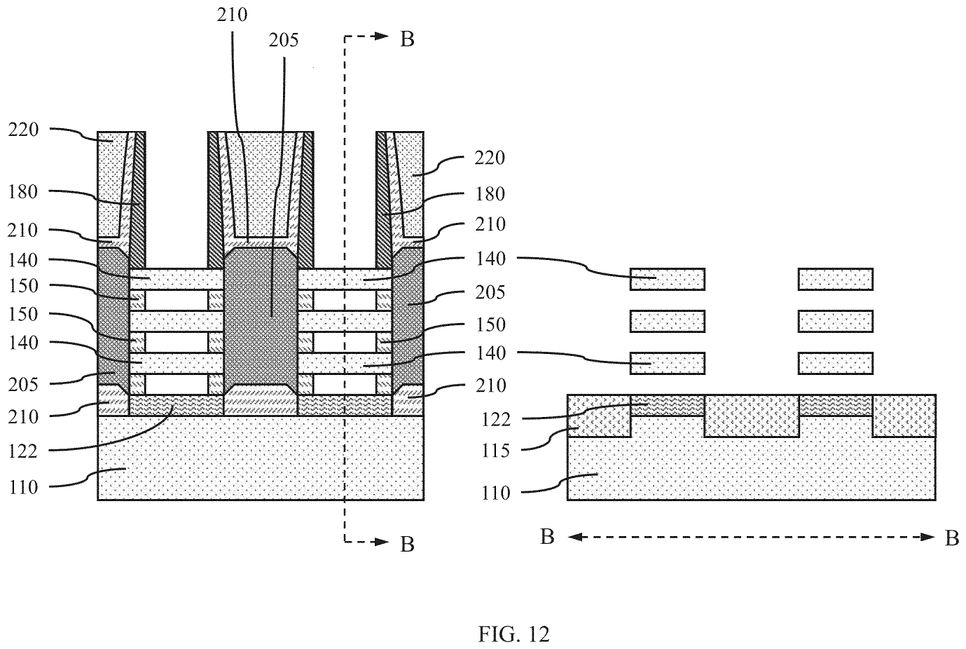

FIG. 12 illustrates perpendicular cross-sectional side views showing removal of the sacrificial sections from the stack, in accordance with an embodiment of the present invention.

In various embodiments, the stack of nanosheet channel sections 140 can be exposed on four sides and suspended between the source/drains 205.

As shown in the B-B cross-section, the sacrificial sections 130 can be removed from between the nanosheet channel sections 140, and from between the bottom insulating slabs 122 and the bottom most nanosheet channel sections 140.

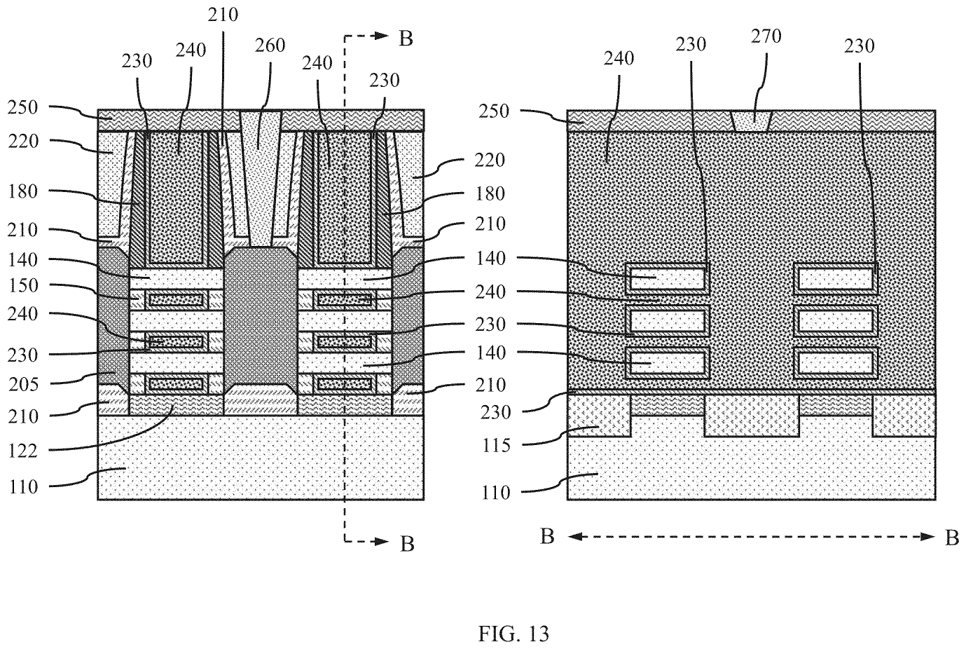

FIG. 13 illustrates perpendicular cross-sectional side views showing formation of an active gate structure on the nanosheet channel sections, in accordance with an embodiment of the present invention.

In one or more embodiments, an active gate structure can be formed on the nanosheet channel sections 140, where the active gate structure can wrap around at least a portion of one or more of the nanosheet channel sections 140. The active gate structure can include a gate dielectric layer 230 formed on the inside sidewalls of the gate sidewall spacers 180, exposed portions of the nanosheet channel sections 140, inside surfaces of the inner spacers 150, and top surface of the bottom insulating slabs 122. The gate dielectric layer 230 can be formed by a conformal deposition, for example, atomic layer deposition (ALD) and plasma enhanced ALD (PEALD).

In various embodiments, the gate dielectric layer 230 can be an electrically insulating dielectric material, including, but not limited to, silicon oxide (SiO) and/or a high-k dielectric, for example, hafnium oxide (HfO), zirconium oxide (ZrO), hafnium zirconium oxide (HfZrO), nitrided hafnium silicates (HfSiON), lanthanum oxide (LaO), and combinations thereof.

In various embodiments, a conductive gate fill 240 can be formed by a conformal deposition of a conductive material on the gate dielectric layer 230.

In various embodiments, the conductive gate fill 240 can be a metal, including, but not limited to, copper (Cu), tungsten (W), ruthenium (Ru), cobalt (Co), molybdenum (Mo), a conductive metal compound, including, but not limited to, tantalum nitride (TaN), titanium nitride (TiN), tantalum carbide (TaC), titanium carbide (TiC), and combinations thereof. The conductive gate fill 240 can be a multilayer of a work function material and a metal.

In various embodiments, a dielectric capping layer 250 can be formed on the gate structures and interlayer dielectric (ILD) layer 220, where the dielectric capping layer 250 can be formed by deposition. The dielectric capping layer 250 can electrically insulate the conductive gate fill 240.

In various embodiments, a source/drain contact 260 can be formed to each of the source/drains 205, where the source/drain contact 260 can be formed through the dielectric capping layer 250, interlayer dielectric (ILD) layer 220, and a portion of the isolation liner 210 using lithography, etching, and deposition of a conductive material.

As shown in the B-B cross-section, the gate dielectric layer 230 and conductive gate fill 240 can fill in the space between the nanosheet channel sections 140, and between the bottom insulating slabs 122 and the bottom most nanosheet channel sections 140. Gate contacts 270 can also be formed to the conductive gate fills 240 through the dielectric capping layer 250.

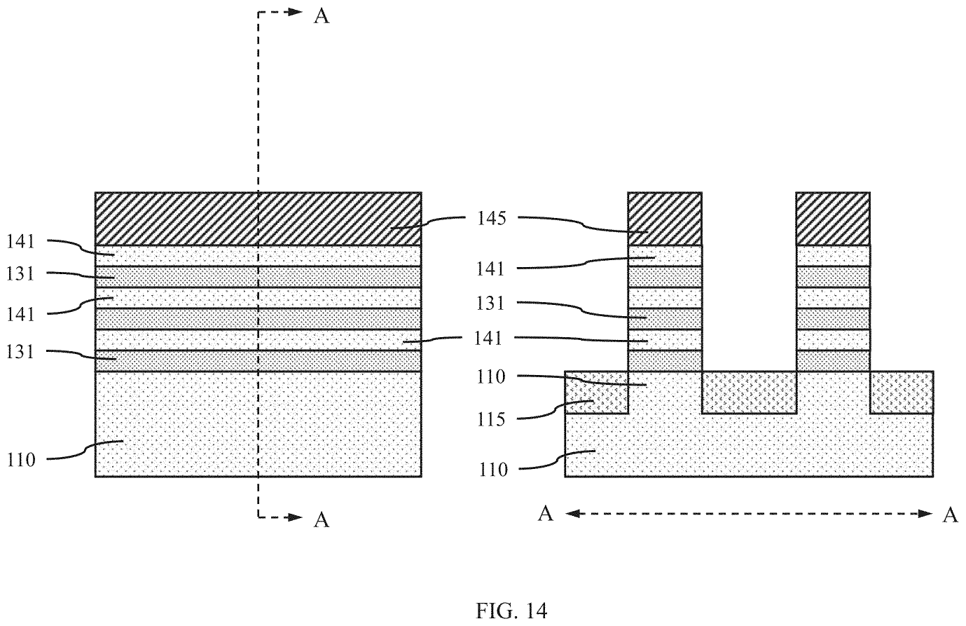

FIG. 14 illustrates perpendicular cross-sectional side views showing a stack of alternating nanosheet channel layers and sacrificial layers directly on a substrate, and shallow trench isolation regions adjacent to the stacks, in accordance with another embodiment of the present invention.

In a different embodiment, a bottom insulating layer 120 can be eliminated, and the stack of alternating nanosheet channel layers 141 and sacrificial layers 131 can be formed directly on a substrate 110. The nanosheet channel layers 141 and sacrificial layers 131 can be formed by epitaxial growth directly from the surface of the substrate.

In various embodiments, a stack template 145 can be formed on the stack of alternating nanosheet channel layers 141 and sacrificial layers 131, where the stack template 145 can be formed by patterning a template layer using lithographic processes and etching. The stack template 145 can be as a mask to pattern the underlying nanosheet channel layers 141 and sacrificial layers 131.

In one or more embodiments, shallow trench isolation (STI) regions 115 can be formed in the substrate 110, where the STI regions 115 can be formed by lithographic processes, etching trenches, and deposition of an electrically insulating dielectric material in the trenches.

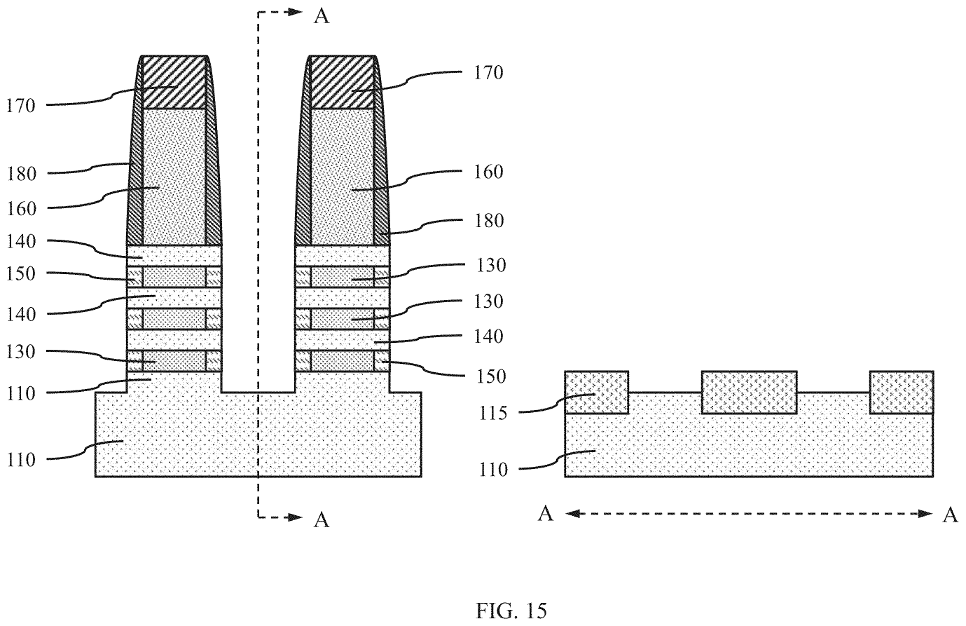

FIG. 15 illustrates perpendicular cross-sectional side views showing formation of a dummy gate structure on a stack of alternating nanosheet channel sections and sacrificial sections directly on the substrate, and inner spacers adjacent to the sacrificial sections, in accordance with another embodiment of the present invention.

In this other embodiment, dummy gate structures, including a dummy gate fill 160 and dummy gate cap 170 can be formed on the stack of alternating nanosheet channel layers 141 and sacrificial layers 131. Gate sidewall spacers 180 can be formed on the dummy gate structure.

In one or more embodiments, the dummy gate cap 170 and gate sidewall spacers 180 can be used as a mask for patterning the nanosheet channel layers 141 and sacrificial layers 131 into stacks of alternating nanosheet channel sections 140 and sacrificial sections 130 using one or more selective directions etches (e.g., RIE). A portion of the substrate between the stacks of alternating nanosheet channel sections 140 and sacrificial sections 130 can also be removed by the etching, where the surface of the substrate can be recessed below the top surface of the shallow trench isolation (STI) regions 115.

In one or more embodiments, inner spacers 150 can be formed in inner spacer cavities created by recessing the sacrificial sections 130, and forming an inner spacer layer in the inner spacer cavities by a conformal deposition. The portions of the inner spacer layer can be removed by etching to form the inner spacers 150.

In this other embodiment, the removal of the portions of the nanosheet channel layers 141 and sacrificial layers 131 can expose the substrate between the dummy gate structures and between the shallow trench isolation regions 115 without having to remove portion(s) of the bottom insulating layer 120, as shown in the A-A cross-section.

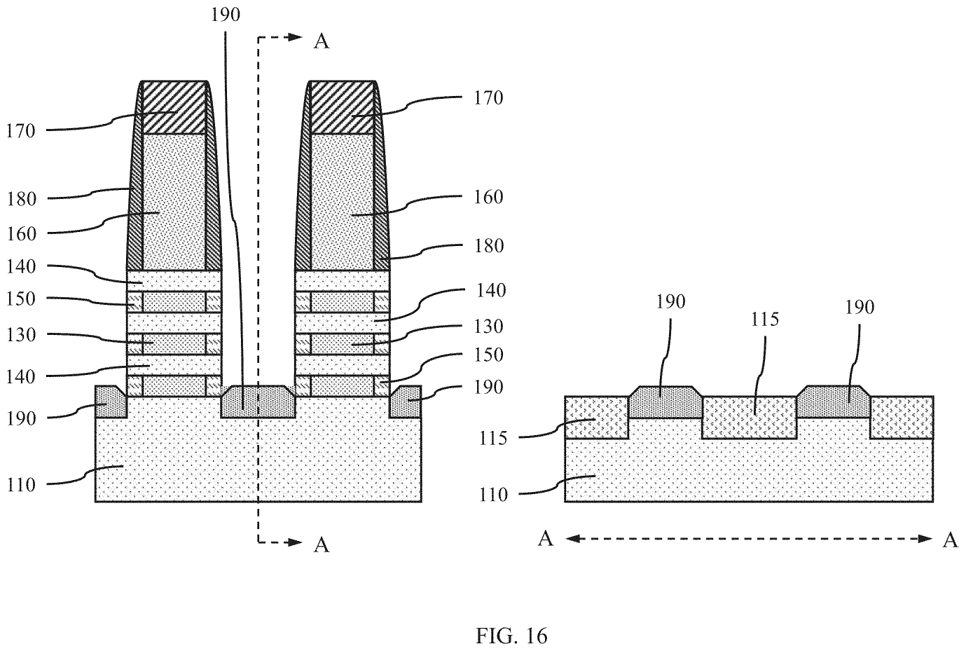

FIG. 16 illustrates perpendicular cross-sectional side views showing formation of sacrificial plates on the substrate between the stacks and shallow trench isolation regions, in accordance with an embodiment of the present invention.

In one or more embodiments, sacrificial plates 190 can be formed on the exposed surface of substrate between the stacks and between the shallow trench isolation regions 115, where the sacrificial plates 190 can be formed by epitaxial growth from the exposed surface of substrate 110. The sacrificial plates 190 can fill in the space between the stacks and shallow trench isolation regions 115. A top surface of the sacrificial plates 190 can be above the top surface of the shallow trench isolation regions 115.

In various embodiments, the sacrificial plates 190 can be, for example, silicon-germanium (SiGe) with a germanium concentration in a range of about 45 atomic percent (at. %) to about 75 at. %, or about 60 at. %. The sacrificial plates 190 can act as buffer layers between a silicon substrate and a silicon germanium source/drain formed on the sacrificial plates 190.

After FIG. 16 the steps shown in FIGS. 4 through 12 can be performed to form source/drains 205 and the isolation liner 210 on and beneath the source/drains 205, and remove the nanosheet channel sections 130.

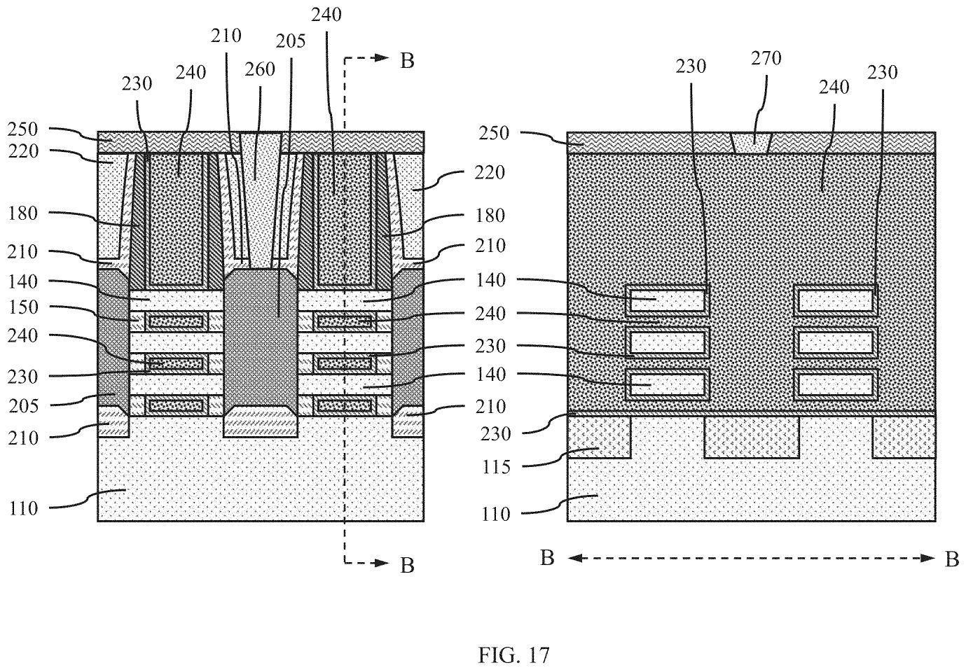

FIG. 17 illustrates perpendicular cross-sectional side views showing formation of source/drains and an active gate structure on the nanosheet channel sections, in accordance with an embodiment of the present invention.

In the different embodiment, the source/drain layer 200 can be grown vertically to form a source/drain 205 that covers the end faces of each of the nanosheet channel sections 140 in the stack. The source/drain 205 can extend above the top most nanosheet channel section 130 and laterally over the shallow trench isolation (STI) regions 115. The source/drains 205 can be adjacent to a lower portion of the gate sidewall spacers 180.

In one or more embodiments, an isolation liner 210 can be formed on and beneath the source/drains 205 and adjacent to the gate sidewall spacers 180, where the isolation liner 210 can be formed by a conformal deposition that fills in the conduit 195. The isolation liner 210 can cover the STI regions 115.

In one or more embodiments, an active gate structure can be formed on the nanosheet channel sections 140. The active gate structure can include a gate dielectric layer 230 formed on the inside sidewalls of the gate sidewall spacers 180, exposed portions of the nanosheet channel sections 140, inside surfaces of the inner spacers 150, and top surface of the substrate 110. The gate dielectric layer 230 can be formed by a conformal deposition, for example, atomic layer deposition (ALD) and plasma enhanced ALD (PEALD). A portion of the gate dielectric layer 230 can be directly on the substrate surface beneath the nanosheet channel sections 140 in the stack(s).

In various embodiments, the gate dielectric layer 230 can be an electrically insulating dielectric material, including, but not limited to, silicon oxide (SiO) and/or a high-k dielectric, for example, hafnium oxide (HfO), zirconium oxide (ZrO), hafnium zirconium oxide (HfZrO), nitrided hafnium silicates (HfSiON), lanthanum oxide (LaO), and combinations thereof.

In various embodiments, a conductive gate fill 240 can be formed by a conformal deposition of a conductive material on the gate dielectric layer 240.

In various embodiments, the conductive gate fill 240 can be a metal, including, but not limited to, copper (Cu), tungsten (W), ruthenium (Ru), cobalt (Co), molybdenum (Mo), a conductive metal compound, including, but not limited to, tantalum nitride (TaN), titanium nitride (TiN), tantalum carbide (TaC), titanium carbide (TiC), and combinations thereof. The conductive gate fill 240 can be a multilayer of a work function material and a metal.

In various embodiments, a dielectric capping layer 250 can be formed on the gate structures and interlayer dielectric (ILD) layer 220, where the dielectric capping layer 250 can be formed by deposition. The dielectric capping layer 250 can electrically insulate the conductive gate fill 240.

In various embodiments, a source/drain contact 260 can be formed to each of the source/drains 205, where the source/drain contact 260 can be formed through the dielectric capping layer 250, interlayer dielectric (ILD) layer 220, and a portion of the isolation liner 210 using lithography, etching, and deposition of a conductive material.

As shown in the B-B cross-section, the gate dielectric layer 230 and conductive gate fill 240 can fill in the space between the nanosheet channel sections 140, and between the substrate surface and the bottom most nanosheet channel sections 140. Gate contacts 270 can also be formed to the conductive gate fills 240 through the dielectric capping layer 250.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ, where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. 1t wild be understood that the spatially relative teams are intended to encompass different orientations of the device in use or operation in addition to the orientation depicted in the FIGS. For example, if the device in the FIGS. is turned over, elements described as “below” “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Having described preferred embodiments of a device and method of fabricating the device (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A gate-all-around device, comprising:
a source/drain on a substrate;
an isolation liner wrapped around the source/drain, where the isolation liner separates the source/drain from the substrate; and
one or more nanosheet channel sections electrically connected to the source/drain.

2. The gate-all-around device of claim 1, further comprising an active gate structure on the one or more nanosheet channel sections, wherein the active gate structure wraps around at least a portion of the one or more nanosheet channel sections, and a source/drain contact that passes through the isolation liner and is in electrical contact with the source/drain.

3. The gate-all-around device of claim 2, wherein the active gate structure includes a gate dielectric layer directly on the substrate.

4. The gate-all-around device of claim 2, further comprising a bottom insulating slab beneath the one or more nanosheet channel sections, wherein the bottom insulating slab separates the active gate structure from the substrate, and the bottom insulating slab is adjacent to at least a portion of the isolation liner.

5. The gate-all-around device of claim 4, wherein the bottom insulating slab and the isolation liner are made of different electrically insulating dielectric materials.

6. The gate-all-around device of claim 5, wherein the source/drain imparts a compressive stress to the one or more nanosheet channel sections.

7. The gate-all-around device of claim 5, wherein the source/drain imparts a tensile stress to the one or more nanosheet channel sections.

8. A gate-all-around device, comprising:
a first source/drain on a substrate;
an isolation liner between the first source/drain and the substrate;
a first set of one or more nanosheet channel sections adjoining the first source/drain on a first side; and
a second set of one or more nanosheet channel sections adjoining a second side of the first source/drain opposite the first side, wherein the first source/drain imparts a stress to both the first set and the second set of nanosheet channel sections without plastic strain relaxation.

9. The gate-all-around device of claim 8, further comprising a second source/drain on an opposite side of the first set of one or more nanosheet channel sections from the first source/drain, wherein the first source/drain and the second source/drain impart a tensile or compressive stress to the first set of one or more nanosheet channel sections.

10. The gate-all-around device of claim 8, wherein the first source/drain imparts a compressive stress to the first set and second set of nanosheet channel sections.

11. The gate-all-around device of claim 8, wherein the first source/drain imparts a tensile stress to the first set and second set of nanosheet channel sections.

12. The gate-all-around device of claim 8, further comprising a bottom insulating slab beneath the one or more nanosheet channel sections, wherein the bottom insulating slab separates the active gate structure from the substrate, and the bottom insulating slab is adjacent to at least a portion of the isolation liner.

13. The gate-all-around device of claim 12, wherein the bottom insulating slab and the isolation liner are made of different electrically insulating dielectric materials.

14. The gate-all-around device of claim 8, further comprising a gate dielectric layer wrapped around at least a portion of each of the one or more nanosheet channel sections of the first set, and a conductive gate fill on the gate dielectric layer.

15. A method of forming a gate-all-around device, comprising:
forming a sacrificial plate on a substrate, wherein the sacrificial plate is adjacent to a stack of alternating one or more nanosheet channel sections and one or more sacrificial sections;
epitaxially growing a source/drain on the sacrificial plate, wherein the source/drain is electrically connected to the one or more nanosheet channel sections;
removing the sacrificial plate; and
forming an isolation liner on and beneath the source/drain.

16. The method of claim 15, wherein the source/drain imparts a compressive stress to the one or more nanosheet channel sections.

17. The method of claim 15, wherein the source/drain imparts a tensile stress to the one or more nanosheet channel sections.

18. The method of claim 15, further comprising removing the one or more sacrificial sections, and forming a gate dielectric layer on at least a portion of the one or more nanosheet channel sections.

19. The method of claim 18, wherein the gate dielectric layer is also formed directly on the substrate beneath the stack.

20. The method of claim 18, wherein a bottom insulating slab is between the one or more nanosheet channel sections and the substrate, and the isolation liner is adjacent to the bottom insulating slab.
